(19) United States
(12) Patent Application Publication
(10) Pub. No.: US 2021/0272809 A1
(43) Pub. Date: Sep. 2, 2021

(54) METHOD AND APPARATUS FOR REDUCING IMPURITY IN A FILM

(71) Applicant: Tokyo Electron Limited, Tokyo (JP)

(72) Inventor: Yoshihisa MATSUBARA, Tokyo (JP)

(73) Assignee: Tokyo Electron Limited, Tokyo (JP)

(21) Appl. No.: 17/165,941

(22) Filed: Feb. 3, 2021

(30) Foreign Application Priority Data
Feb. 27, 2020 (JP) 2020-031937

(51) Int. Cl. H01L 21/225; H01L 21/285; H01L 27/11582; H01L 21/67; C23C 16/42; C23C 16/455; C23C 16/56

(52) U.S. Cl. CPC H01L 21/2257; H01L 21/28518; H01L 27/11582; H01L 21/32137; C23C 16/42; C23C 16/45525; C23C 16/56; H01L 21/67207

(57) ABSTRACT

A method of reducing an impurity in a film begins by forming a metal film on a silicon film, the silicon film containing an impurity imparting electrical conductivity to silicon. The method proceeds to heat-treating the metal film to form a metal silicide region on the silicon film, and then removing the metal silicide region from the silicon film.

### CROSS-REFERENCE TO RELATED APPLICATION

This application claims the benefit of priority to a Japanese patent application as Serial No. 2020-031937, filed Feb. 27, 2020, the contents of which is hereby incorporated by reference in its entirety.

### TECHNICAL FIELD

The present disclosure relates to a method of reducing an impurity and an apparatus for reducing an impurity.

### BACKGROUND

In recent years, NAND flash memory has been stacked vertically. Three dimensional (3D) NAND memory is stacked vertically and formed by a batch process to avoid increasing process costs.

### SUMMARY

According to an embodiment of the present disclosure, a method of reducing an impurity in a film is provided. The method includes forming a metal film to form a silicide region on a silicon film containing an impurity imparting electrical conductivity to silicon, and then removing the metal silicide region from the silicon film.

### BRIEF DESCRIPTION OF THE DRAWINGS

FIG. 1 is a perspective view illustrating an exemplary structure of a memory cell array of a 3D-NAND memory;

FIG. 2 is a sectional view illustrating an exemplary configuration of a NAND string;

FIG. 3 is a flowchart of an exemplary method of reducing an impurity according to an embodiment;

FIGS. 4A to 4D illustrate the process of removing an impurity from a silicon film containing the impurity by the method of reducing an impurity according to the embodiment;

FIG. 5 illustrates silicidation;

FIGS. 6A to 6D illustrate an example of reducing the concentration of an impurity by employing the method of reducing an impurity according to the embodiment;

FIGS. 7A to 7C illustrate a procedure for forming a single crystal silicon layer;

FIGS. 8A to 8F illustrate a first procedure for forming a single crystal silicon layer according to the embodiment;

FIGS. 9A to 9E illustrate a second procedure for forming a single crystal silicon layer according to the embodiment;

FIGS. 10A to 10D illustrate a third procedure for forming a single crystal silicon layer according to the embodiment;

FIG. 11 illustrates an exemplary apparatus for reducing an impurity according to an embodiment; and

FIG. 12 illustrates another exemplary apparatus for reducing an impurity according to the embodiment.

FIG. 13 illustrates an exemplary apparatus for reducing an impurity according to the present disclosure.

FIG. 14 illustrates exemplary processing circuitry that performs computer-based operations in accordance with the present disclosure.

### DETAILED DESCRIPTION

Hereinafter, embodiments of the method of reducing an impurity and the apparatus for reducing an impurity disclosed in the present application will be described in detail with reference to the drawings. However, the disclosed method of reducing an impurity and apparatus for reducing an impurity are by no means limited by these embodiments. In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

There are instances in which a silicon film containing an impurity is formed. For example, 3D-NAND memory may contain P (phosphorus) as an impurity in a polysilicon film that is to be a channel layer. For such a 3D-NAND memory, there is a need for miniaturization and increased density of the memory through thinning of a channel layer and/or increasing of the stacking number. The present inventors have recognized that when a channel layer containing an impurity is thinned, the memory becomes prone to increased transistor variability due to the subthreshold swing reduced by the impurity. For this reason, the present inventors have developed a technique of reducing the concentration of an impurity in a silicon film containing the impurity.

Methods and apparatuses for reducing an impurity according to the present disclosure will now be described. Hereinafter, a case of removing an impurity from a silicon film that is to be a channel layer of a 3D-NAND memory will be described as a primary example.

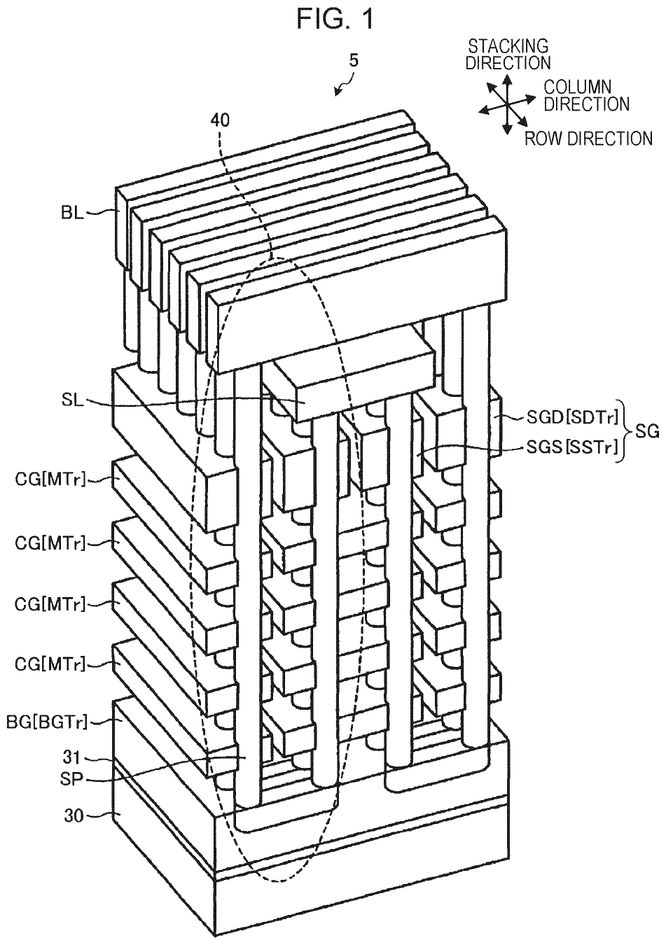

First, an exemplary structure of a 3D-NAND memory will be described. FIG. 1 is a perspective view illustrating an exemplary structure of a memory cell array 5 of a 3D-NAND memory. In FIG. 1, some components including a memory film are not illustrated for the sake of easy view.

As illustrated in FIG. 1, the memory cell array 5 of a 3D-NAND memory is provided with a plurality of word lines (control gates CGs), a plurality of bit lines BLs, and a plurality of source lines SLs. The memory cell array 5 of a 3D-NAND memory is further provided with a plurality of back gates BGs, a plurality of source-side select gates (select gate sources SGSs), and a plurality of drain-side select gates (select gate drains SGDs).

In the memory cell array 5, each memory cell transistor MTr that stores data is arranged at each intersection between a plurality of stacked word lines (control gates CGs) and a semiconductor pillar SP. A NAND string 40 is composed of a plurality of memory cell transistors MTr connected in series along the semiconductor pillar SP.

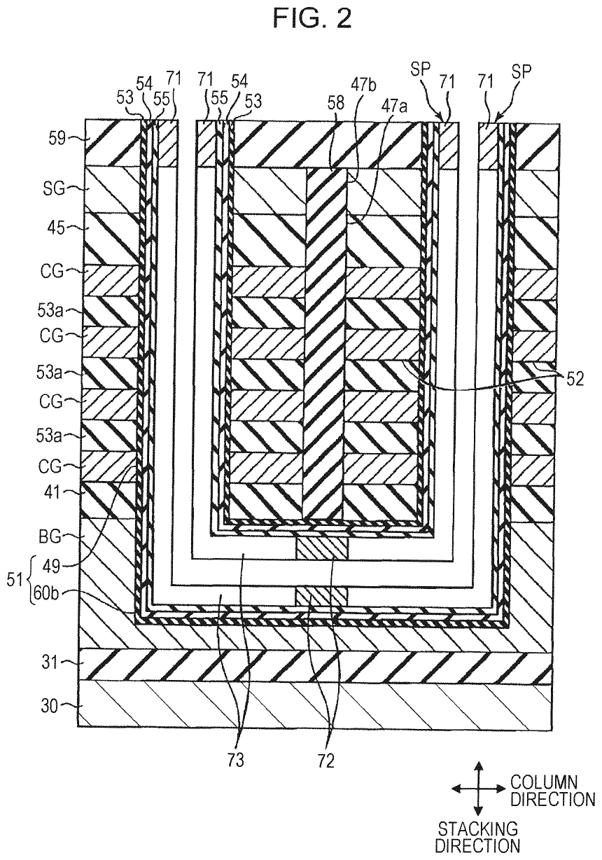

FIG. 2 is a sectional view illustrating an exemplary configuration of the NAND string 40. In FIG. 2, the sectional configuration of the NAND string 40 in the column direction is illustrated in further detail.

As illustrated in FIGS. 1 and 2, the NAND string 40 is formed above a semiconductor substrate 30 in the memory cell array 5. The NAND string 40 includes a back gate BG, a plurality of control gates CGs, a select gate SG, semiconductor pillars SPs, and memory films including blocking insulating layer 53, charge trapping layer 54, and tunnel insulating layer 55.

In the present specification and the like, although the blocking insulating layer 53, the charge trapping layer 54, and the tunnel insulating layer 55 are referred to as a memory film, the memory film is not necessarily a film that stores data.

The back gate BG is formed above the semiconductor substrate 30 and an insulating layer 31 is formed between the back gate BG and the semiconductor substrate in the stacking direction. The back gate BG extends in a planar manner. The back gate BG is formed as an electrically conductive layer, such as a doped silicon layer implanted with an impurity (P (phosphorus), for example).

A plurality of control gates CGs are formed above the back gate BG in the stacking direction and an insulating layer 41 is formed between the back gate BG and the plurality of control gates CGs in the stacking direction. An interelectrode insulating layer 53a is formed between control gates CGs in the stacking direction. In other words, a plurality of interelectrode insulating layers 53a and a plurality of control gates CGs are alternately stacked above insulating layer 41, which is stacked above the back gate BG along the stacking direction.

Control gates CGs may be formed, for example, as a doped silicon layer implanted with an impurity (boron B, for example). However, control gates CGs may include other types of materials, such as silicon layers, non-silicon layers, and doped silicon layers implanted with other impurities.

The select gate SG is formed above the uppermost control gate CG in the stacking direction. An insulating layer 45 is formed between the uppermost control gate CG and the select gate SG in the stacking direction. The select gate SG may formed, for example, as a doped silicon layer implanted with an impurity in the same manner as the control gate CG. However, the select gate SG may include other types of materials, such as silicon layers, non-silicon layers, and doped silicon layers implanted with other impurities.

Above the select gate SG in the stacking direction, a source line SL is formed. An insulating layer 59 is formed between the select gate SG and the source line SL. Further above in the stacking direction, another insulating layer and a bit line BL are formed.

A U-shaped memory hole 51 is provided within the stacked select gate SG, control gates CGs, back gate BG, insulating layers 41, 45, and 59, and the interelectrode insulating layers 53a. The U-shaped memory hole 51 is composed of a pair of through holes 49 placed side by side in the column direction and a connecting hole 60b that connects the bottom edges of the pair of through holes 49. The through holes 49 are formed to extend in the stacking direction in the select gate SG, the control gates CGs, the insulating layers 41, 45, and 59, and the interelectrode insulating layers 53a. The connecting hole 60b is formed to extend in the column direction in the back gate BG.

The control gates CGs, the insulating layers 41, 45, and 59, and the interelectrode insulating layers 53a are provided with a slit 47a that extends in the row and stacking directions between the pair of through holes 49. Consequently, the control gates CGs, the insulating layers 41, 45, and 59, and the interelectrode insulating layers 53a are split in the row direction. Further, the select gate SG is provided with an opening 47b that extends in the row and stacking direction on top of the slit 47a to expose the slit 47a. Consequently, the select gate SG is split in the row direction, thereby making either one a drain-side select gate SGD and the other a source-side select gate SGS. The slit 47a and the opening 47b are buried with an insulator 58.

Each memory film is composed of the blocking insulating layer 53, the charge trapping layer 54, and the tunnel insulating layer 55.

The blocking insulating layer 53 is formed on an inner surface of the U-shaped memory hole 51. In other words, the blocking insulating layer 53 is formed on the select gate SG, the control gates CG, the back gate BG, the interelectrode insulating layers 53a, and the insulating layers 41 and 45 exposed to the U-shaped memory hole 51. The blocking insulating layer 53 is formed, for example, as an insulating layer, such as silicon oxide or silicon nitride, or a stacked structure thereof. However, blocking insulating layer 53 may be formed of other materials or compositions.

The blocking insulating layer 53 may be integrated with the interelectrode insulating layers 53a. In other words, the interelectrode insulating layers 53a may be in the form in which the blocking insulating layer 53 is buried in each gap 52 between two control gates CGs neighboring in the stacking direction.

The charge trapping layer 54 is formed on the blocking insulating layer 53 within the U-shaped memory hole 51. The charge trapping layer 54 is formed, for example, as an insulating layer, such as silicon oxide or silicon nitride, or a stacked structure thereof. However, charge trapping layer 54 may be formed of other materials or compositions.

The tunnel insulating layer 55 is formed on the charge trapping layer 54 within the U-shaped memory hole 51. The tunnel insulating layer 55 is formed, for example, as an insulating layer, such as silicon oxide or silicon nitride. However, tunnel insulating layer 55 may be formed of other materials or compositions.

Each semiconductor pillar SP is formed on the tunnel insulating layer 55 within the U-shaped memory hole 51. In other words, the semiconductor pillar SP is composed of a pair of columnar sections formed on the memory film within the pair of through holes 49 and a connecting section formed on the memory film within the connecting hole 60b. The semiconductor pillar SP acts as a channel as well as source/drain diffusion layers of the NAND string 40.

The select gate SG and the control gates CGs may be silicided in the portions in contact with the insulator 58.

The semiconductor pillar SP as well as various gates and the memory film formed therearound constitutes various transistors. The NAND string 40 is formed along the semiconductor pillar SP as a channel.

More specifically, the control gates CGs, the semiconductor pillar SP, and the memory film formed therebetween constitute memory cell transistors MTr. Moreover, the select gate SG (drain-side select gate SGD and source-side select gate SGS), the semiconductor pillar SP, and the memory film formed therebetween constitute select transistors (drain-side select transistor SDTr and source-side select transistor SSTr). Further, the back gate BG, the semiconductor pillar SP, and the memory film formed therebetween constitute a back gate transistor BGTr.

Although referred to as a memory film, the memory film does not store data in the select transistor or the back gate transistor BGTr. Further, the back gate transistor BGTr is controlled to be always in the conductive state during operation.

The semiconductor pillar SP includes a doped silicide layer 71, non-doped silicide layer 72, and a single crystal silicon layer 73.

The doped silicide layer 71 is formed on the tunnel insulating layer 55 within the U-shaped memory hole 51 that is provided in the insulating layer 59. The doped silicide layer 71 comprises, for example, Ni disilicide (NiSi₂) implanted with P. The doped silicide layer 71 acts as source/drain of the select transistors SDTr and SSTr. Further, the doped silicide layer 71 may have the crystal structure of NiSi₂ but a composition different than the composition of NiSi₂, e.g. a different composition and/or formed of other materials. In other words, the doped silicide layer 71 may have the crystal structure of NiSi₂ at least partially. Accordingly, the doped silicide layer 71 may partially contain Ni silicide having another Ni—Si composition, such as nickel monosilicide (NiSi).

The concentration of P in the doped silicide layer 71 is 1.0×10²⁰ atoms/cm³ or more, for example. Consequently, it is possible to suppress, in the doped silicide layer 71, migration of Ni disilicide due to metal-induced-lateral-crystallization (MILC).

The doped silicide layer 71 may contain, without being limited to Ni disilicide, Co silicide, or may contain, without being limited thereto, any metal element that forms a silicide with Si. Hereinafter, an example in which the doped silicide layer 71 comprises Ni disilicide will be described.

Further, without being limited to P, the doped silicide layer 71 may be implanted with As or with B in the case of p-channel. Moreover, without being limited thereto, any dopant material may be employed provided that the migration of Ni disilicide due to MILC is suppressed through implantation in the doped silicide layer 71.

The single crystal silicon layer 73 is continuously formed on the tunnel insulating layer 55 within the U-shaped memory hole 51 that is provided in the select gate SG, the control gates CGs, the insulating layers 41 and 45, and the interelectrode insulating layers 53a. In addition, the single crystal silicon layer 73 is also continuously formed on part of the tunnel insulating layer 55 within the U-shaped memory hole 51 that is provided in the back gate BG. The end face of the single crystal silicon layer 73 is formed in contact with the end face of the doped silicide layer 71. The single crystal silicon layer 73 acts as a channel of the NAND string 40 (select transistors SDTr and SSTr, memory cell transistors MTr, and back gate transistors BGTr).

The junction interface between the doped silicide layer 71 and the single crystal silicon layer 73 is positioned higher than the top face of the select gate SG. This is because there is a concern about deterioration in transistor characteristics, such as the increase in off-state leakage current in the select transistors SDTr and SSTr, when the junction interface between the doped silicide layer 71 and the single crystal silicon layer 73 is positioned lower than the top face of the select gate SG, in other words, when the doped silicide layer 71 overlaps a gate-controllable region. However, without being limited thereto, the junction interface between the doped silicide layer 71 and the single crystal silicon layer 73 may be positioned within any range in which the select transistors SDTr and SSTr act as select transistors of the NAND string 40.

The single crystal silicon layer 73 is formed by converting amorphous silicon into a single crystal through a MILC process using the non-doped silicide layer 72 as a catalyst. The single crystal silicon layer 73 is formed through solid-phase epitaxy of amorphous silicon using the non-doped silicide layer 72 as the growth edge. For this reason, the crystal orientation of the single crystal silicon layer 73 is the same as the crystal orientation of the non-doped silicide layer 72, or having a difference in crystal orientation of ±20° or less of the non-doped silicide layer 72.

In the 3D-NAND memory as described above, the diffusion layer of the select transistor SG is formed as the doped silicide layer 71 implanted with an impurity (phosphorus (P), for example) and the channel layer is formed as the single crystal silicon layer 73 in the semiconductor pillar SP. However, the doped silicide layer 71 may be implanted with an impurity of another material or composition.

The 3D-NAND memory configuration, as described above, improves erasing characteristics and increase the channel current when compared to conventional technologies. However, with this 3D-NAND memory configuration, the charge mobility decreases as the channel becomes thinner or the stacking number increases. In other words, the channel current decreases, thereby lowering the operating speed.

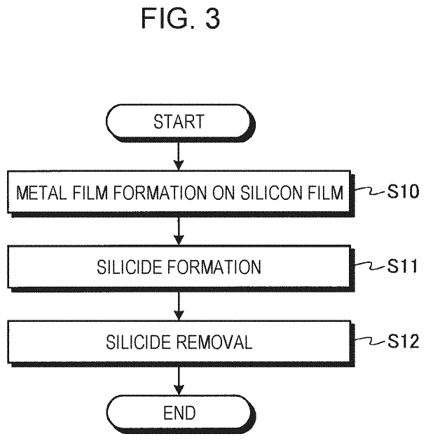

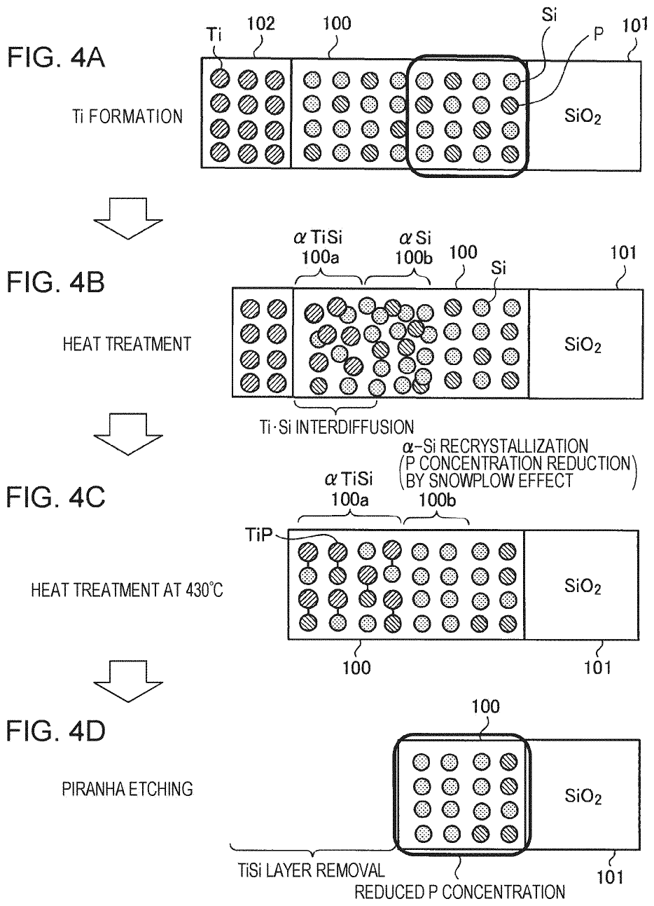

For this reason, the present inventors have developed a method to remove an impurity in the channel. FIG. 3 is a flowchart of an exemplary method of reducing an impurity according to an embodiment. In the present embodiment, an impurity contained in a silicon film is reduced through the procedure shown in the flowchart of FIG. 3. Hereinafter, with reference to FIGS. 4A to 4D, the process of removing an impurity (P, for example) from a silicon film (single crystal silicon layer 73, for example) through the procedure shown in the flowchart of FIG. 3 will be described. FIGS. 4A to 4D illustrate the process of removing an impurity from a silicon film containing the impurity by the method of reducing an impurity according to the embodiment.

A metal film for forming a metal silicide is formed on a silicon film containing an impurity that imparts electrical conductivity to silicon (step S10). Exemplary impurities that impart electrical conductivity to silicon include light metals, such as elements having a mass smaller than titanium (Ti). Other exemplary impurities that impart electrical conductivity to silicon include phosphorus (P), boron (B), arsenic (As), oxygen (O), and carbon (C). Exemplary metal films for forming a metal silicide include titanium (Ti), tungsten (W), cobalt (Co), and nickel (Ni). Such a metal film is formed on a silicon film by any of chemical vapor deposition (CVD), atomic layer deposition (ALD), and sputtering, for example, or another process. The single crystal silicon layer 73 may contain P as an impurity, for example. On the single crystal silicon layer 73, a metal film, such as Ti, is formed by CVD. FIG. 4A illustrates a silicon film 100 that simulates the single crystal silicon layer 73. The silicon film 100 is formed on a SiO₂ film 101. The silicon film 100 contains, in addition to Si, P as an impurity. On the silicon film 100, a metal film 102 of Ti is formed, for example.

Next, a metal silicide derived from the metal film is formed on the silicon film (step S11). For example, a silicide is formed by heating the silicon film to a temperature within a predetermined temperature range in which silicon and the metal film form a monosilicide. In some embodiments, such a predetermined temperature range may be 400° C. or higher and 700° C. or lower, for example. In the silicon film, solid-phase amorphization reactions occur due to heating and a silicide is formed through reactions between silicon and the metal film. On this occasion, a snowplow phenomenon occurs, thereby moving the impurity within the silicon film. This snowplow phenomenon of the impurity is driven by two types of solid-phase reactions. The first step is solid-phase amorphization at the interface between titanium and silicon. The second step is the phase transition from amorphous TiSi to C49-TiSi₂ and finally to C54-TiSi₂. For example, as illustrated in FIGS. 4B and 4C, the silicon film 100, when heated to 430° C. through heat treatment, undergoes solid-phase amorphization reactions from the metal film 102 side. Consequently, an amorphous TiSi region (metal silicide region) 100a due to reactions between titanium and silicon is formed on the metal film side 102 in the silicon film 100. Moreover, an amorphous Si region 100b is formed following the amorphous TiSi region 100a in the silicon film 100. On this occasion, the first step of the snowplow phenomenon occurs and moves P (phosphorus) in the silicon film 100 to the amorphous TiSi side and to the Sift side. In other words, phosphorus in the silicon film 100 is swept out to both sides. In the amorphous TiSi region 100a, TiP is formed through reactions between titanium and phosphorus or phosphorus is dissolved in TiSi. Meanwhile, amorphous Si in the region 100b is recrystallized after the end of heating, thereby reducing the concentration of P in the silicon film.

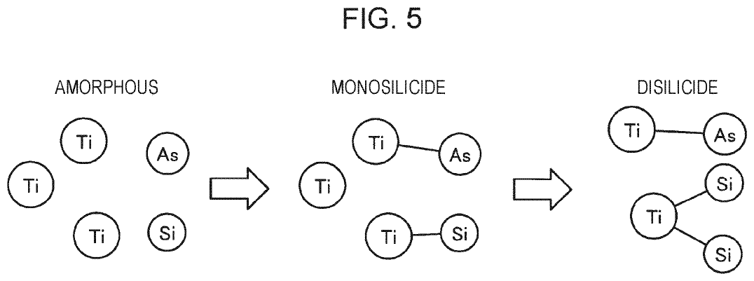

Here, when the temperature of the heat treatment for silicidation is high, a disilicide but not a monosilicide is formed. FIG. 5 illustrates silicidation. In the silicon film 100, silicon is further supplied from a silicon substrate when the temperature of the heat treatment for silicidation is higher than 700° C. As a result, silicon and titanium in amorphous TiSi are further reacted to form the disilicide. The disilicide is difficult to remove even by a wet process having selectivity over an oxide film described hereinafter. For this reason, monosilicide of titanium is formed in step S11 by performing heat treatment at a temperature at which a monosilicide is formed without forming a disilicide. For example, when the impurity is phosphorus, a temperature at which titanium forms the monosilicide is 400° C. or higher and 700° C. or lower. Such a temperature for forming a monosilicide varies depending on the types of impurity or the concentrations of impurity.

When the concentration of an impurity increases, the temperature for forming a monosilicide or a disilicide also rises. This is because titanium preferentially bonds with the impurity, thereby causing a shortage of silicon. For this reason, the heat treatment temperature in step S11 is preset to form a monosilicide depending on the types of impurity and the concentrations of impurity. Here, the heat treatment temperature may be set by retrieving a temperature corresponding to the type of an impurity and the concentration of the impurity from the data of stored temperatures for monosilicide formation depending on the types of impurity and the concentrations of impurity. As a method of forming thick amorphous TiSiₓ, it is also effective to perform heat treatment in a hydrogen atmosphere at about 550° C. This allows insertion of hydrogen between Ti atoms and stabilizes an amorphous layer, thereby attaining the thickness of about 15 nm.

Referring back to FIGS. 3 and 4A to 4D, the metal silicide region is removed from the silicon film (step S12). For example, the monosilicide region is removed from the silicon film by wet etching using either a piranha solution (mixture of sulfuric acid and aqueous hydrogen peroxide) or an ammonia-peroxide mixture (mixture of aqueous ammonia and aqueous hydrogen peroxide). However, the method is not limited to the use of a piranha solution or an ammonia-peroxide mixture, and other solutions or mixtures may be used. Here, the silicide region may be removed by dry etching, such as plasma etching. As illustrated in FIG. 4D, the amorphous TiSi region 100a is removed from the silicon film 100 by a wet process using piranha solution, for example. Consequently, the phosphorus concentration decreases in the remaining silicon film 100. In addition, the silicon film 100 is thinned. For example, when the initial thickness of the silicon film 100 is set to 20 to 50 nm and the thickness of the titanium metal film 102 is set to 7 nm, the amorphous TiSi region 100a is formed at a thickness of about 14 nm and the amorphous Si region 100b is formed at a thickness of about 7 nm. By removing the amorphous TiSi region 100a, the silicon film 100 can be thinned by about 7 nm.

The method of reducing an impurity according to the embodiment can reduce the impurity concentration in a silicon film by repeating, as necessary, the above-described steps S10 to S12. For example, by repeating the above-described steps S10 to S12, it is possible to further reduce the phosphorus concentration in the silicon film 100. Moreover, the method of reducing an impurity according to the embodiment can thin a silicon film while reducing the impurity concentration.

As in the foregoing, the method of reducing an impurity according to the embodiment can reduce the concentration of an impurity in a silicon film containing the impurity. For example, by carrying out the method of reducing an impurity according to the embodiment, the phosphorus concentration can be reduced in the single crystal silicon layer 73 of the above-described 3D-NAND memory.

Here, the embodiment is described using an exemplary case of reducing the phosphorus concentration in the single crystal silicon layer 73 of the 3D-NAND memory but is not limited thereto. The silicon film containing an impurity may be a silicon film other than the single crystal silicon layer 73 of the 3D-NAND memory.

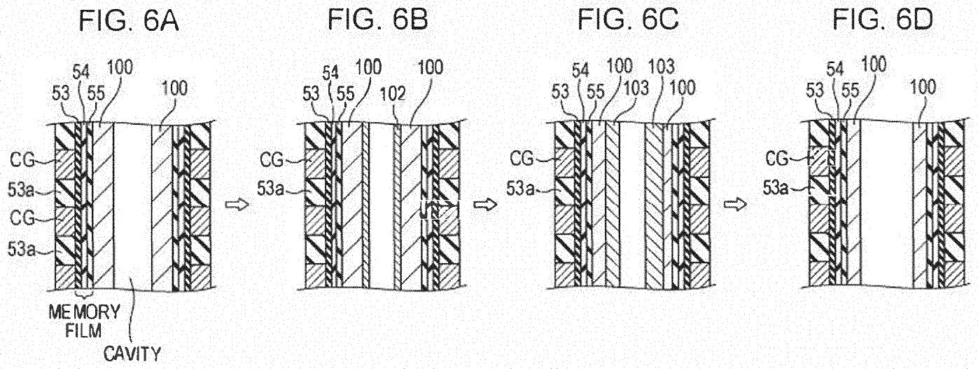

Next, an example, in which the concentration of an impurity in a silicon film containing the impurity of a 3D-NAND memory is reduced by employing the method of reducing an impurity according to the embodiment, will be described. FIGS. 6A to 6D illustrate an example of reducing the concentration of an impurity by employing the method of reducing an impurity according to the embodiment. In particular, FIGS. 6A to 6D schematically illustrate a partial configuration of the U-shaped memory hole 51 of the NAND string 40.

On the inner wall of the U-shaped memory hole 51, the blocking insulating layer 53, the charge trapping layer 54, and tunnel insulating layer 55 are formed as a memory film. Within the U-shaped memory hole 51, a phosphorus-containing silicon film 100 is formed on the tunnel insulating layer 55, and the silicon film 100 constitutes a hollow structure (FIG. 6A) whose cavity extends in the height direction (direction perpendicular to the surface of the semiconductor substrate 30). Here, the silicon film 100 corresponds to the single crystal silicon layer 73 of FIG. 2, for example. On the inner wall of the cavity of the silicon film 100, a Ti (titanium) metal film 102 is formed by CVD (FIG. 6B). Subsequently, through heat treatment of heating in an inert gas atmosphere at 430° C., for example, a monosilicide region 103 is formed (FIG. 6C). The heat treatment may be performed at another temperature, however. After that, the monosilicide region 103 may be removed from the silicon film 100 (FIG. 6D), for example, by wet etching using either piranha solution (mixture of sulfuric acid, hydrogen peroxide, and water) or ammonia-peroxide mixture (mixture of ammonia, hydrogen peroxide, and water), or some other solution or mixture. Consequently, the phosphorus concentration in the remaining silicon film 100 is reduced.

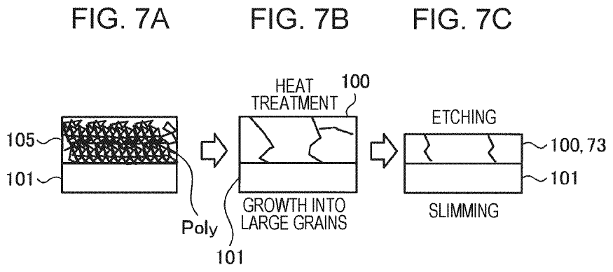

Next, a procedure for reducing the concentration of phosphorus in the single crystal silicon layer 73 of the 3D-NAND memory by applying the method of reducing an impurity according to the embodiment will be described. First, a conventional procedure for forming the single crystal silicon layer 73 will be described. FIGS. 7A to 7C illustrate a procedure for forming the single crystal silicon layer 73. In FIGS. 7A to 7C, an exemplary conventional procedure for forming a single crystal silicon layer 73 is illustrated.

In the procedure of FIGS. 7A to 7C, for example, after forming a SiO₂ film 101 that is to be the tunnel insulating layer 55, a phosphorus-containing polysilicon layer 105 is formed on the SiO₂ film 101 (FIG. 7A). Subsequently, the polysilicon layer 105 is subjected to heat treatment at 800° C., for example, to grow large grains, thereby forming a silicon film 100 (FIG. 7B). The formed silicon film 100 contains phosphorus. The silicon film 100 is then subjected to pretreatment for removing a silicon oxide film on the surface of the silicon film 100 and slimmed, for example, by dry etching into a target thickness of the silicon film 100 to form a single crystal silicon layer 73 (FIG. 7C). In the 3D-NAND memory, it is possible to reduce variations in threshold voltage by forming, through slimming, a thin single crystal silicon layer 73 that acts as a channel.

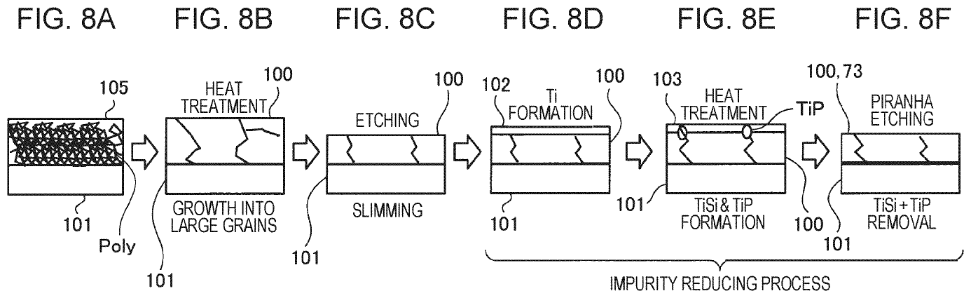

Next are figures that illustrate a procedure for forming the single crystal silicon layer 73 of the 3D-NAND memory by applying the method of reducing an impurity of the embodiment. FIGS. 8A to 8F illustrate a first procedure for forming a single crystal silicon layer 73 according to the embodiment. FIGS. 8A to 8C are the same as the conventional procedure illustrated in FIGS. 7A to 7C.

In the example of FIGS. 8A to 8F, following FIG. 8C, a metal film 102 is formed on the silicon film 100 by CVD or some other film formation process (FIG. 8D). In this example, a Ti metal film 102 of 5 nm in thickness is formed by CVD. Subsequently, through heat treatment, a monosilicide region 103 is formed on the silicon film 100 (FIG. 8E). For example, through heat treatment in an inert gas atmosphere at 430° C. for 10 seconds, a monosilicide region 103 of amorphous TiSi is formed at a thickness of about 10 nm. However, the heat treatment may be performed at another temperature. In some embodiments, the monosilicide region 103 may contain TiP. In addition, in the monosilicide region 103, phosphorus may be dissolved in TiSi in some cases.

Next, the monosilicide region 103 is removed from the silicon film 100 by wet etching, or another process, to form a single crystal silicon layer 73 (FIG. 8F). For example, the single crystal silicon layer 73 is formed by removing the monosilicide region 103 from the silicon film 100 by using, for example, a liquid containing sulfuric acid and aqueous hydrogen peroxide diluted with water (1:1:4). Through this first procedure, it is possible to reduce the concentration of phosphorus in the single crystal silicon layer 73. Moreover, through the first procedure, it is also possible to form a thinned single crystal silicon layer 73.

As illustrated in FIG. 8C, the single crystal silicon layer 73 is thinned through slimming by dry etching or wet etching (wet etching using tetramethylammonium hydroxide (TMAH), for example). In addition, the single crystal silicon layer 73 can also be thinned by removing the monosilicide region 103, as illustrated in FIG. 8F. Here, the thickness of the monosilicide region 103 can be changed by the thickness of the metal film 102.

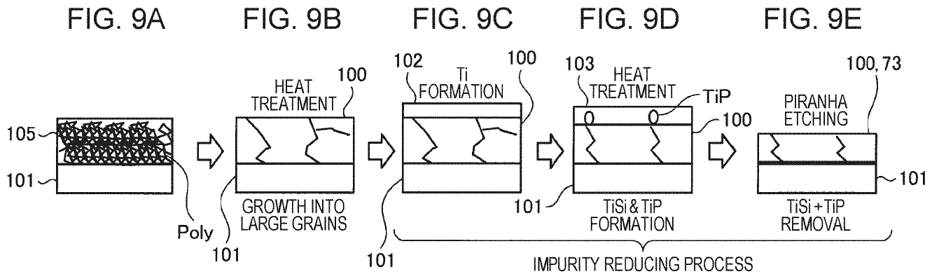

Accordingly, a procedure for forming the single crystal silicon layer 73 may be as follows. FIGS. 9A to 9E illustrate a second procedure for forming a single crystal silicon layer 73 according to the embodiment. FIGS. 9A and 9B are regarded as the same as the conventional procedure illustrated in FIGS. 7A and 7B.

In the example of FIGS. 9A to 9E, following FIG. 9B, a metal film 102 is formed, depending on the thickness to be removed, on the resulting silicon film 100 by CVD or some other film formation process (FIG. 9C). In this example, a Ti metal film 102 of 10 nm in thickness is formed by CVD. Subsequently, through heat treatment, a monosilicide region 103 is formed on the silicon film 100 (FIG. 9D). For example, through heat treatment in an inert gas atmosphere at 430° C. for 10 seconds, a monosilicide region 103 of amorphous TiSi containing TiP is formed at a thickness of about 20 nm. However, the heat treatment may be performed at another temperature.

After that, the monosilicide region 103 is removed from the silicon film 100 by wet etching, or another process to form a single crystal silicon layer 73 (FIG. 9E). Here, the single crystal silicon layer 73 is formed by removing the monosilicide region 103 from the silicon film 100 by using, for example, a liquid containing sulfuric acid and aqueous hydrogen peroxide diluted with water (1:1:4). Through this second procedure as well, it is possible to reduce the concentration of phosphorus in the single crystal silicon layer 73. Moreover, through the second procedure as well, it is also possible to form a thinned single crystal silicon layer 73. Further, the second procedure can eliminate the step of slimming illustrated in FIG. 7C. Since the second procedure can reduce a step compared with the first procedure, it is possible, for example, to reduce production costs.

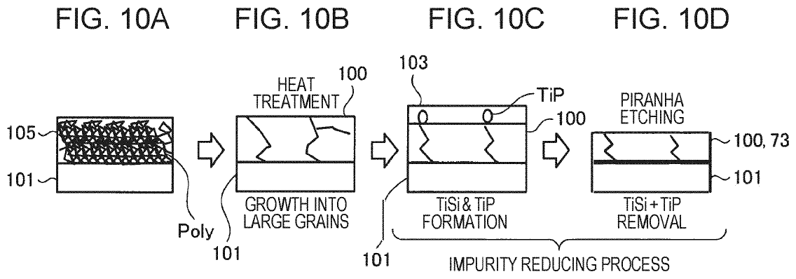

Further, a procedure for forming a single crystal silicon layer 73 may be as follows. FIGS. 10A to 10D illustrate a third procedure for forming a single crystal silicon layer 73 according to the embodiment. FIGS. 10A and 10B are regarded as the same as the conventional procedure illustrated in FIGS. 7A and 7B.

In the example of FIGS. 10A to 10D, following FIG. 10B, a metal film is formed, depending on the thickness to be removed, on the resulting silicon film 100 by ALD using a metal chloride gas as a source. However, the metal film may be formed by another film formation process. In this example, a metal film of 20 nm in thickness is formed by ALD using TiCl₄. ALD is carried out, for example, in an atmosphere at 400° C. or higher and 700° C. or lower and more preferably in an atmosphere at 400° C. or higher and 600° C. or lower. However, the ALD process is not limited to these temperature ranges and may be performed at other temperatures. Consequently, simultaneously with the formation of a titanium metal film, a monosilicide region 103 is formed in the silicon film 100 through reactions between titanium and silicon (FIG. 10C). The monosilicide region 103 may be formed at a thickness of 15 nm, for example. After that, a single crystal silicon layer 73 is formed by removing the monosilicide region 103 from the silicon film 100 by wet etching or some other process (FIG. 10D). Here, the single crystal silicon layer 73 is formed by removing the monosilicide region 103 from the silicon film 100 by using, for example, a liquid containing sulfuric acid and aqueous hydrogen peroxide diluted with water (1:1:4). Through this third procedure, it is possible to reduce the concentration of phosphorus in the singe crystal silicon layer 73. In addition, through the third procedure, it is also possible to form a thinned single crystal silicon layer 73. Further, by forming the metal film through ALD, the third procedure can simultaneously perform, as one step, the step of forming a metal film on a silicon film and the step of forming a silicide in the silicon film. Consequently, since the third procedure can further reduce a step compared with the second procedure, it is possible, for example, to reduce production costs.

Next, an apparatus for carrying out the method of reducing an impurity according to the embodiment will be described. Hereinafter, a case in which the respective steps of the method of reducing an impurity according to the embodiment are carried out by a cluster apparatus, which is a plurality of apparatus combined, will be described.

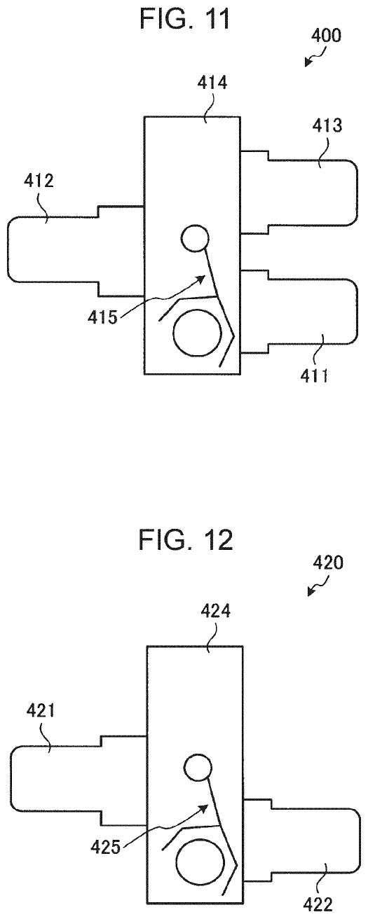

FIG. 11 illustrates an exemplary apparatus 400 for reducing an impurity according to an embodiment. The apparatus 400 is a cluster apparatus includes a film forming apparatus 411, an annealing apparatus 412, and an etching apparatus 413, which are connected to a conveyor apparatus 414 that includes a conveyor robot 415. In the apparatus 400, a substrate above which a silicon film containing an impurity has been formed is conveyed, corresponding to each step in the method of reducing an impurity, to the film forming apparatus 411, the annealing apparatus 412, or the etching apparatus 413 by the conveyor robot 415. The conveyor apparatus 414 is referred to as “platform”.

The etching apparatus 413 performs pretreatment of removing a silicon oxide film on the surface of a silicon film. Conveyor apparatus 414 and conveyor robot 415 convey the silicon film to film formation apparatus 411. The film formation apparatus 411 forms, on the silicon film, a metal film for forming a silicide. For example, when an impurity such as P is to be removed from the silicon film, a Ti metal film is formed on the silicon film. Conveyor apparatus 414 and conveyor robot 415 convey the silicon film to annealing apparatus 412.

Subsequently, the annealing apparatus 412 performs heat treatment to form a silicide. For example, through heat treatment, a silicide layer of amorphous TiSi is formed on the silicon film. On this occasion, a monosilicide region 103 contains TiP in some cases. In addition, in the monosilicide region, phosphorus is dissolved in TiSi in some cases. Conveyor apparatus 414 and conveyor robot 415 convey the silicon film to etching apparatus 413. After that, the etching apparatus 413 removes the silicide region.

FIG. 12 illustrates another exemplary apparatus 420 for reducing an impurity according to another embodiment. The apparatus 420 is a cluster apparatus including a film forming apparatus 421 and an etching apparatus 422 connected to a conveyor apparatus 424 that includes a built-in conveyor robot 425. In the apparatus 420, a substrate above which a silicon film containing an impurity has been formed is conveyed, corresponding to each step in the method of reducing an impurity, to the film forming apparatus 421 or the etching apparatus 422 by the conveyor robot 425. The film forming apparatus 421 is, for example, an ALD apparatus that can elevate the temperature to about 700° C. and that is configured to form a silicide through ALD. Moreover, the film forming apparatus 421 can also perform heat treatment in a vacuum.

For example, the film forming apparatus 421 can form a silicide, on a substrate that has been subjected to pretreatment of removing a silicon oxide film on the surface of a silicon film, through formation of a metal film by ALD. The etching apparatus 422 then removes the silicide.

The apparatus 400 illustrated in FIG. 11 and the apparatus 420 illustrated in FIG. 12 can reduce the concentration of an impurity by repeating, as necessary, the respective steps of the above-described method of reducing an impurity according to the embodiment. For example, the etching apparatuses 413 and 422 may include a glow discharge optical emission spectrometer. Consequently, the apparatus 400 and/or the apparatus 420 can measure the concentration of phosphorus from glow discharge by GD-OES (glow discharge optical emission spectrometry). By repeating the above-described steps S10 to S12 until the concentration of phosphorus in the silicon film is reduced to a predetermined level, the phosphorus concentration level can be lowered.

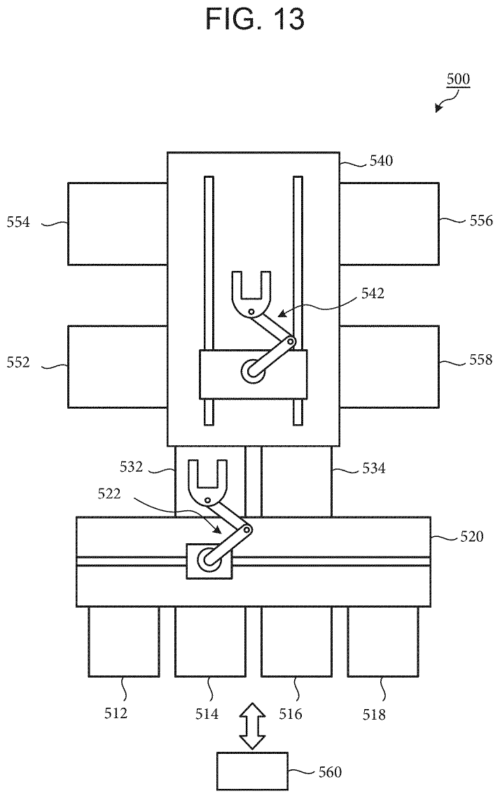

FIG. 13 illustrates apparatus 500 according to another exemplary embodiment of the present disclosure. In such an exemplary embodiment, apparatus 500 corresponds to apparatuses 400 and 420 illustrated in FIGS. 11 and 12. Apparatus 500 includes conveyor apparatus 540 (that operates at a reduced pressure with respect to film forming apparatus 552, annealing apparatus 554, and etching apparatuses 556, and 558) that includes a conveyer robot 542 to transport a substrate W, to and from film forming apparatus 552, annealing apparatus 554, and etching apparatuses 556, and 558. The conveyor apparatus 540 has a vacuum transportation chamber that interfaces with load lock chambers 532 and 534. The film forming apparatus 552, annealing apparatus 554, and etching apparatus 556 and 558 are connected to the conveyor apparatus 540 and partitioned from load lock chambers 532 and 534.

Load lock chambers 532 and 534 provide a way to compartmentalize environments between the conveyor apparatus 540 and the loader device 520. The loader device 520 has a carrier placing table in which a carrier is placed. The carrier holds, for example, twenty five substrates and when moved in and out of the apparatus 500 is placed on a front surface of the loader device 520. The loader robot 522 transports substrates between the carrier placing table and the load lock chambers 532 and 534. Carriers are exchanged in respective load ports 512-518.

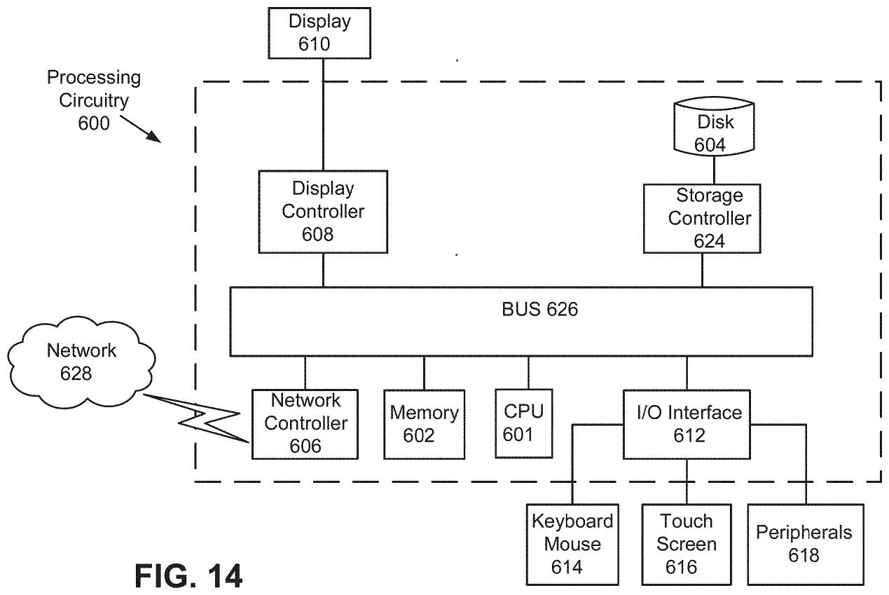

A controller 560, in this example is a microcontroller, although a computer (local dedicated computer, or distributed computer) and/or processing circuitry such as that described in FIG. 14 may be used as an alternative of controller circuitry that is configured by computer code to perform control operations described herein.

FIG. 14 is a block diagram of processing circuitry for performing computer-based operations described herein. FIG. 14 illustrates processing circuitry 700 that may be used to control any computer-based and cloud-based control processes, descriptions or blocks in flowcharts can be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art. The various elements, features, and processes described herein may be used independently of one another or may be combined in various ways. All possible combinations and sub-combinations are intended to fall within the scope of this disclosure.

In FIG. 14, the processing circuitry 600 includes a CPU 601 which performs one or more of the control processes described above/below. The process data and instructions may be stored in memory 602. These processes and instructions may also be stored on a storage medium disk 604 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry 600 communicates, such as a server or computer. The processes may also be stored in network based storage, cloud-based storage or other remote accessible storage and executable by processing circuitry 600.

Further, the claimed advancements may be provided as a utility application, background daemon, or component of an operating system, or combination thereof, executing in conjunction with CPU 601 and an operating system such as Microsoft Windows, UNIX, Solaris, LINUX, Apple MAC-OS and other systems known to those skilled in the art.

The hardware elements in order to achieve the processing circuitry 600 may be realized by various circuitry elements. Further, each of the functions of the above described embodiments may be implemented by circuitry, which includes one or more processing circuits. A processing circuit includes a particularly programmed processor, for example, processor (CPU) 601, as shown in FIG. 14. A processing circuit also includes devices such as an application specific integrated circuit (ASIC) and conventional circuit components arranged to perform the recited functions.

In FIG. 14, the processing circuitry 600 includes a CPU 601 which performs the processes described above. The processing circuitry 600 may be a general-purpose computer or a particular, special-purpose machine. In one embodiment, the processing circuitry 600 becomes a particular, special-purpose machine when the processor 601 is programmed to perform ESC in-situ replacement by controlling voltages and robot arms to replace the ESC without exposing the reaction chamber 610 to an external atmosphere. The processing circuitry 600 may be in or locally communicable to substrate processing apparatus 500. In some embodiments, processing circuitry 600 may be remote from substrate processing apparatus 500, providing processing instructions to substrate processing apparatus 500 via network 628.

Alternatively, or additionally, the CPU 601 may be implemented on an FPGA, ASIC, PLD or using discrete logic circuits, as one of ordinary skill in the art would recognize. Further, CPU 601 may be implemented as multiple processors cooperatively working in parallel to perform the instructions of the inventive processes described above.

The processing circuitry 600 in FIG. 14 also includes a network controller 606, such as an Intel Ethernet PRO network interface card from Intel Corporation of America, for interfacing with network 628. As can be appreciated, the network 628 can be a public network, such as the Internet, or a private network such as an LAN or WAN network, or any combination thereof and can also include PSTN or ISDN sub-networks. The network 628 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

The processing circuitry 600 further includes a display controller 608, such as a graphics card or graphics adaptor for interfacing with display 610, such as a monitor. A general purpose I/O interface 612 interfaces with a keyboard and/or mouse 614 as well as a touch screen panel 616 on or separate from display 610. General purpose I/O interface also connects to a variety of peripherals 618 including printers and scanners.

The general-purpose storage controller 624 connects the storage medium disk 604 with communication bus 626, which may be an ISA, EISA, VESA, PCI, or similar, for interconnecting all of the components of the processing circuitry 600. A description of the general features and functionality of the display 610, keyboard and/or mouse 614, as well as the display controller 608, storage controller 624, network controller 606, and general purpose I/O interface 612 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

Herein, the embodiments are described using an exemplary case of reducing the concentration of an impurity in a silicon film formed in a 3D-NAND memory but are by no means limited thereto. The method of reducing an impurity according to the embodiment is applicable to the reduction of an impurity in a silicon film formed above a substrate in general. In accordance with a method and apparatus an in the present disclosure, it is possible to reduce the concentration of an impurity in a silicon film that contains the impurity.

As in the foregoing, the method of reducing an impurity according to the embodiment includes: forming a metal silicide region on a silicon film containing an impurity that imparts electrical conductivity to silicon; and removing the metal silicide region from the silicon film. Consequently, the method of reducing an impurity according to the embodiment can reduce the concentration of an impurity in a silicon film containing the impurity.

The impurity is any of phosphorus, boron, arsenic, oxygen, and carbon; and the metal silicide region contains any of titanium, tungsten, cobalt, and nickel. Titanium, tungsten, cobalt, and nickel can form a silicide on a silicon film. Consequently, the method of reducing an impurity according to the embodiment can reduce the concentration of phosphorus, boron, arsenic, oxygen, or carbon contained in the silicon film by removing the silicide region from the silicon film.

When formed on a silicon film, a metal film is formed by either chemical vapor deposition (CVD) or atomic layer deposition (ALD). CVD can form a metal film in a stable manner, whereas ALD can form a silicide while forming a metal film.

In the step of forming a silicide, a monosilicide is formed by heating the silicon film to a temperature within a predetermined temperature range in which the silicon film and the metal film form a monosilicide. Consequently, the method of reducing an impurity according to the embodiment can form a monosilicide on the silicon film and reduce the concentration of an impurity in the silicon film by removing the resulting monosilicide region.

The predetermined temperature range is set to 400° C. to 700° C. Consequently, the method of reducing an impurity according to the embodiment can form a monosilicide on the silicon film in a stable manner.

In the step of removing, the monosilicide region is removed from the silicon film by wet etching using either piranha solution or ammonia-peroxide mixture. Consequently, the method of reducing an impurity according to the embodiment can remove the monosilicide region. Moreover, piranha solution and ammonia-peroxide mixture can remove the monosilicide region while suppressing damage to an oxide film. Consequently, damage to an oxide film can be suppressed in memories, such as 3D-NAND memories, by removing the monosilicide region from the silicon film through wet etching using either piranha solution or ammonia-peroxide mixture.

The silicon film for which the impurity concentration has been reduced is used as a silicon film that is to be a channel layer of a 3D-NAND memory. Consequently, it is possible to suppress variations in electrical characteristics of transistors even when the channel is thinned or the stacking number is increased.

The apparatuses 400 and 420 according to the embodiment includes a first forming section (film forming apparatuses 411, 421), a second forming section (annealing apparatus 412, film forming apparatus 421), and a removal section (etching apparatus 413, 422). The first forming section forms, on a silicon film containing an impurity that imparts electrical conductivity to silicon, a metal film for forming a silicide. The second forming section forms, on the silicon film, a silicide derived from the metal film. The removal section removes the silicide region from the silicon film. Consequently, the apparatus for reducing an impurity 400 according to the embodiment can reduce the concentration an impurity in a silicon film that contains the impurity.

Although the embodiments are described as in the foregoing, the embodiments disclosed herein are mere examples in all the aspects and thus should not be considered as limiting. The above-described embodiments can actually be realized in various forms. Further, the above-described embodiments may be omitted, replaced, or modified in various ways without departing from the claims and the spirit thereof.

For example, the embodiments are described using an exemplary case in which the substrate is a semiconductor wafer. However, the substrate is by no means limited thereto and may be another substrate, such as a glass substrate.

The embodiments disclosed herein are mere examples in all the aspects and thus should not be considered as limiting. The above-described embodiments can actually be realized in various forms. Further, the above-described embodiments may be omitted, replaced, or modified in various ways without departing from the attached claims and the spirit thereof

What is claimed is:

1. A method of reducing an impurity in a film, the method comprising:
forming a metal film on a silicon film, the silicon film containing an impurity;
heat-treating the metal film to form a metal silicide region on the silicon film; and
removing the metal silicide region from the silicon film.

2. The method of reducing an impurity according to claim 1, wherein
the silicon film is disposed above a substrate,
the silicon film constitutes a hollow structure having a cavity that extends in a direction perpendicular to a surface of the substrate, and
the metal silicide region is formed on an inner wall of the hollow structure.

3. The method of reducing an impurity according to claim 1, wherein
the impurity is any of phosphorus, boron, arsenic, oxygen, and carbon, and
the metal silicide region contains any of titanium, tungsten, cobalt, and nickel.

4. The method of reducing an impurity according to claim 1, wherein the metal silicide region contains a monosilicide.

5. The method of reducing an impurity according to claim 1, wherein the metal silicide region contains a compound of the impurity with a metal that constitutes the metal silicide region.

6. The method of reducing an impurity according to claim 1, wherein the impurity is dissolved in the metal silicide region.

7. The method of reducing an impurity according to claim 1, wherein the metal silicide region is formed by atomic layer deposition (ALD) in an atmosphere at 400° C. or higher and 700° C. or lower.

8. The method of reducing an impurity according to claim 1, wherein the heat-treating the metal film is performed in an atmosphere at 400° C. or higher and 700° C. or lower.

9. The method of reducing an impurity according to claim 1, wherein the removing the metal silicide region is performed by dry etching.

10. The method of reducing an impurity according to claim 1, wherein the removing the metal silicide region is performed by wet etching.

11. The method of reducing an impurity according to claim 10, wherein an etchant for the wet etching is a mixture of sulfuric acid and aqueous hydrogen peroxide or a mixture of ammonium hydroxide and aqueous hydrogen peroxide.

12. The method of reducing an impurity according to claim 1, wherein the silicon film is a silicon film that is to be a channel layer of a 3D-NAND memory.

13. An apparatus for reducing an impurity in a film, the apparatus comprising:
a film formation apparatus configured to from a metal film on a silicon film, the silicon film containing an impurity;
an annealing apparatus configured to heat-treat the metal film to form a metal silicide region on the silicon film; and
an etching apparatus configured to perform an etch to remove the metal silicide region from the silicon film.

14. The apparatus for reducing an impurity according to claim 13, wherein
the silicon film is disposed above a substrate,
the silicon film constitutes a hollow structure having a cavity that extends in a direction perpendicular to a surface of the substrate, and
the metal silicide region is formed on an inner wall of the hollow structure.

15. The apparatus for reducing an impurity according to claim 13, wherein
the impurity is any of phosphorus, boron, arsenic, oxygen, and carbon, and
the metal silicide region contains any of titanium, tungsten, cobalt, and nickel.

16. The apparatus for reducing an impurity according to claim 13, wherein the metal silicide region contains a monosilicide.

17. The apparatus for reducing an impurity according to claim 13, wherein
the metal silicide region contains a compound of the impurity with a metal that constitutes the metal silicide region.

18. The apparatus for reducing an impurity according to claim 13, wherein
the impurity is dissolved in the metal silicide region.

19. A method of reducing an impurity in a film, the method comprising:
forming a metal silicide region on a silicon film, the silicon film containing an impurity imparting electrical conductivity to silicon; and
removing the metal silicide region from the silicon film.

20. The method of reducing an impurity in a film according to claim 19, wherein the forming the metal silicide region is performed by atomic layer deposition (ALD) in an atmosphere at 400° C. or higher and 700° C. or lower.
